(19) United States
(12) Patent Application Publication
(10) Pub. No.: US 2015/0276900 A1
(43) Pub. Date: Oct. 1, 2015

(54) Transmitting Antenna Device and Magnetic Resonance Imaging System

(71) Applicants: Stephan Biber, Erlangen (DE); Klaus Huber, Effeltrich (DE); Johanna Dorothee Schöpfer, Erlangen (DE)

(72) Inventors: Stephan Biber, Erlangen (DE); Klaus Huber, Effeltrich (DE); Johanna Dorothee Schöpfer, Erlangen (DE)

(21) Appl. No.: 14/672,563

(22) Filed: Mar. 30, 2015

(30) Foreign Application Priority Data
Mar. 31, 2014 (DE) 102014206070.2

(51) Int. Cl. G01R 33/36; G01R 33/48; G01R 33/343; G01R 33/341; H01Q 7/00; G01R 33/34

(52) U.S. Cl. CPC G01R 33/3678; H01Q 7/00; G01R 33/34092; G01R 33/343; G01R 33/341; G01R 33/48

(57) ABSTRACT

A transmission antenna apparatus is provided to emit transmission magnetic fields in magnetic resonance imaging scanners. The transmission antenna apparatus includes at least a first flat antenna and a second flat antenna. The first flat antenna is arranged in relation to the second flat antenna in such a way that first areas, formed in the planar extent of partial structures of the first flat antenna in each case situated in the same plane, are opposite to second areas, formed in the planar extent of partial structures of the second flat antenna in each case situated in the same plane, in a manner mirrored in a mirror plane. The first flat antenna and the second flat antenna, as part of the structure thereof, share a first path, situated on the mirror plane, over the full length of the path. The magnetic resonance imaging scanner has such a transmission antenna apparatus.

### CROSS-REFERENCE TO RELATED APPLICATIONS

This application claims the benefit of DE 10 2014 206 070.2, filed on Mar. 31, 2014, which is hereby incorporated by reference in its entirety.

### TECHNICAL FIELD

The embodiments relate to a transmission antenna apparatus.

### BACKGROUND

In magnetic resonance imaging, circularly polarized transmission magnetic fields are required for exciting magnetic resonances. For this purpose, magnetic resonance imaging scanners may have whole-body antennas. There are research approaches, however, that consider the generation of transmission magnetic fields with local antenna structures that are matched to the anatomy of the body.

In magnetic resonance imaging practice, however, such antenna structures are hardly used since they place particular requirements on the design of the magnetic resonance imaging scanners, particularly in view of the transmission power. Therefore, instruments with whole-body antennas are also routinely used for examining a body part, since these are more complicated to realize than pure reception coils and a whole-body antenna is a component of the magnetic resonance imaging unit in any case.

### SUMMARY AND DESCRIPTION

The scope of the present invention is defined solely by the appended claims and is not affected to any degree by the statements within this summary. The present embodiments may obviate one or more of the drawbacks or limitations in the related art.

It is an object of the embodiments to develop an improved transmission antenna apparatus. In particular, the transmission antenna apparatus may be optimized in view of the transmission power. Furthermore, it is an object of the embodiments to develop a magnetic resonance imaging scanner, in which a transmission antenna apparatus for generating a transmission magnetic field is embodied with optimization of the transmission power.

The transmission antenna apparatus is configured for emitting transmission magnetic fields in the magnetic resonance imaging scanners, wherein the transmission antenna apparatus includes at least a first flat antenna and a second flat antenna. The first flat antenna is arranged in relation to the second flat antenna in such a way that first areas, formed in the planar extent of partial structures of the first flat antenna in each case situated in the same plane, are opposite to second areas, formed in the planar extent of partial structures of the second flat antenna in each case situated in the same plane, in a manner mirrored in a mirror plane and the first flat antenna and the second flat antenna, as part of the structure thereof, share a first path, situated on the mirror plane, over the full length of the path.

Transmission power efficient imaging of body parts, (e.g., shoulder imaging), is possible by the transmission antenna apparatus. The transmission antenna apparatus moreover is advantageous in that, in view of the structure and arrangement thereof, the transmission antennas may be brought closer to the body (e.g., body parts) to be examined. The path shared over the full length in this case provides the decoupling of the flat antennas, which leads to further optimization of the transmission antenna apparatus.

Furthermore, the transmission antenna apparatus is configured to the body anatomy, e.g., the shoulder part. The optimization of the transmission power is supported, inter alia, by the option, provided by this configuration, of coming closer to the body. Furthermore, another advantage emerging from this arrangement is that the transmission antenna apparatus may be integrated into conventional designs of existing shoulder housings in magnetic resonance imaging scanners. As a result of the advantage of partly surrounding the body, the apparatus also has the advantageous effect that the generated magnetic field does not drop off as strongly as in the case of surface antennas not completely surrounding the body.

The aforementioned advantages are amplified, (e.g., in view of shoulder imaging), by the development in which the transmission antenna apparatus includes a third flat antenna of coplanar partial structures, wherein the third flat antenna is arranged in such a way that a plane spanned by the partial structures thereof in a planar extent is orthogonal to the mirror plane and shares a second path as part of the structure thereof, over the full length of the second path with the first flat antenna and also a third path as part of the structure thereof, over the full length of the third path with the second flat antenna. This is because the shoulder is reached from three sides as a result of this.

If the transmission antenna apparatus is configured in such a way that one or more of the flat antennas are embodied as planar antennas, the advantage that planar flat antennas may be formed in a very space-saving manner and may be integrated particularly easily into a magnetic resonance imaging scanner comes to bear.

The transmission antenna apparatus may be configured in such a way that at least one of the flat antennas is embodied as a loop antenna. Here, in the case of a planar loop antenna, a planar direction of the extent of the loop may refer to those directions of extent along which the area enclosed by the loop of the loop antenna extends. To the extent that the loop antenna does not have a completely planar embodiment, planar directions of extent may refer to all directions along which tangents on the loop of the loop antennas extend.

If the transmission antenna apparatus is configured such that the partial structures of the flat antennas are embodied such that, in respect of the areas thereof emerging in the planar extent, they are maximized in terms of size to take at least almost full advantage of the space available in accordance with the design of the magnetic resonance imaging scanners, a field drop-off of the generated magnetic fields may be reduced or homogenized.

If the transmission antenna apparatus has a feed apparatus embodied for opposite polarity feed of the first and third loop antenna, this contributes to the decoupling of the loops and may be combined with the development in which the feed apparatus is formed such that the feed apparatus feeds the third loop antenna with an additional phase offset, it develops the advantage that a quadrature excitation is achieved.

If the transmission antenna apparatus is characterized in that the feed apparatus is configured such that the individual feeds are brought about such that the ratio of the values of loop currents of the three loop antennas, generated by the feed, may be set in relation to one another, there is the option of additionally adjusting or optimizing the circular excitation.

This may be achieved by virtue of the transmission antenna apparatus being developed such that the transmission antenna apparatus has a feed such that it is formed by at least one phase shifter ( ) and/or at least one 180° phase shifted coupler device (-COUPLER).

The transmission antenna apparatus may be configured such that common conductor sections form the common paths. This enables or assists decoupling.

An apparatus supplying ideal values in practice is provided if the transmission antenna apparatus is formed by an arrangement substantially following the arrangement of loop antennas in accordance with FIG. 1, e.g., if it has at least some of the circuitry elements depicted in FIG. 2.

The magnetic resonance imaging scanner has a transmission antenna apparatus, as described above.

In addition to the effects given by the transmission antenna apparatus and the developments thereof, the magnetic resonance imaging scanner substantially has the advantage of enabling imaging of bodies that require a very homogeneous field in the human body.

### BRIEF DESCRIPTION OF THE DRAWINGS

FIG. 1 depicts an exemplary embodiment of a three-dimensional antenna structure formed from flat antennas embodied by loop antennas in a spatial illustration, with the decoupling of the individual elements by common conductors, and

FIG. 2 depicts a representation of an exemplary embodiment of the circuitry for the antenna feed.

### DETAILED DESCRIPTION

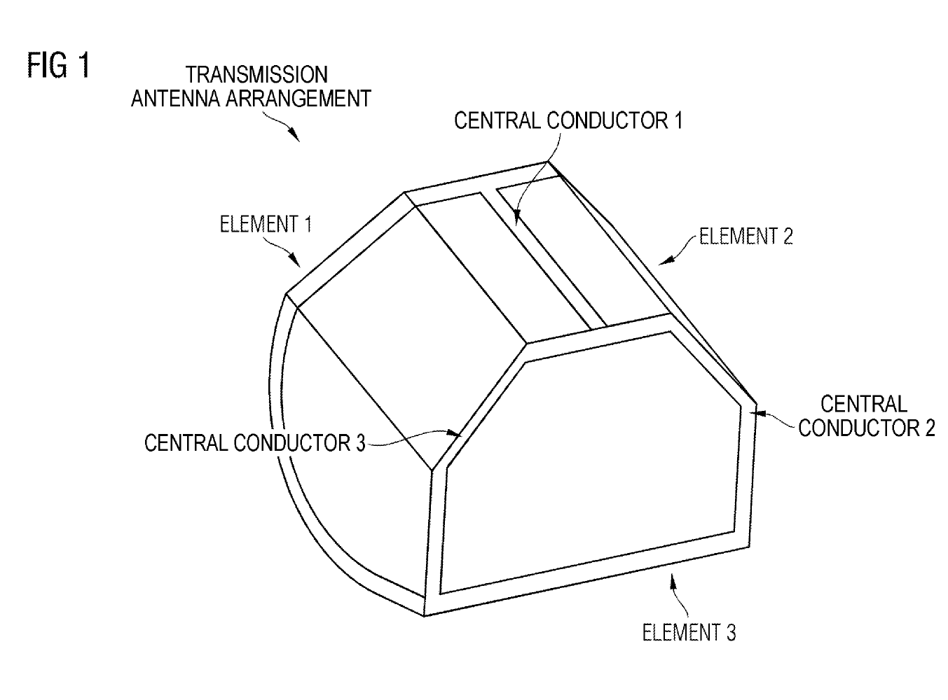

FIG. 1 depicts a connected antenna structure as an exemplary embodiment, which, in the case of a separate observation, is depicted as an arrangement including three elements ELEMENT 1 . . . 3.

Here, each element (ELEMENT 1 . . . 3) is configured as a loop antenna applied to a carrier circuit board and including a plurality of conductor pieces.

First element ELEMENT 1 is, from a spatial point of view, arranged virtually parallel to a second element ELEMENT 2 and the two elements are connected by way of a first central conductor CENTRAL CONDUCTOR 1 provided by a common conductor piece. The two elements ELEMENT 1 . . . 2 therefore surround the shoulder from the front and backside of a human torso.

This arrangement is closed to form a spatial structure by a third element ELEMENT 3 attached orthogonally to the first two elements ELEMENT 1 . . . 2. The spatial structure is placed around a shoulder part of the torso such that a field generated for shoulder imaging may be effected in a targeted and uniform manner on the three sides of the shoulder reachable from the outside.

Here, a field drop-off for surface coils may be slightly reduced or homogenized by selecting the largest possible antenna elements, e.g., when the areas surrounded by the loops are maximized.

The depicted exemplary embodiment may also be advantageously developed in a complementary manner by virtue of the opposing, parallel elements ELEMENT 1 . . . 2 being excited in anti-phase and, moreover, the third element ELEMENT 3 being fed with an additional phase offset thereto and hence a quadrature excitation being achieved.

In FIG. 1, it is furthermore possible to identify that the third element ELEMENT 3 has common conductor pieces with the second element ELEMENT 2, which common conductor pieces form a second central conductor CENTRAL CONDUCTOR 2, and the third element has common conductor pieces with the first element ELEMENT 1, which common conductor pieces form a third CENTRAL CONDUCTOR 3. The antenna elements are advantageously decoupled in each case by way of the respective common central conductor CENTRAL CONDUCTOR 1 . . . 3.

This type of decoupling is particularly efficient in relation to the load dependence of the antenna structure compared to, e.g., decoupling with additional decoupling capacitors.

Compared to inductive decoupling, the common central conductor CENTRAL CONDUCTOR 1 . . . 3 is also advantageous due to the ideal use of space or ideal element size. This simplifies the integration in a magnetic resonance imaging scanner and, moreover, the previously mentioned optimization by the size is therefore also further supported.

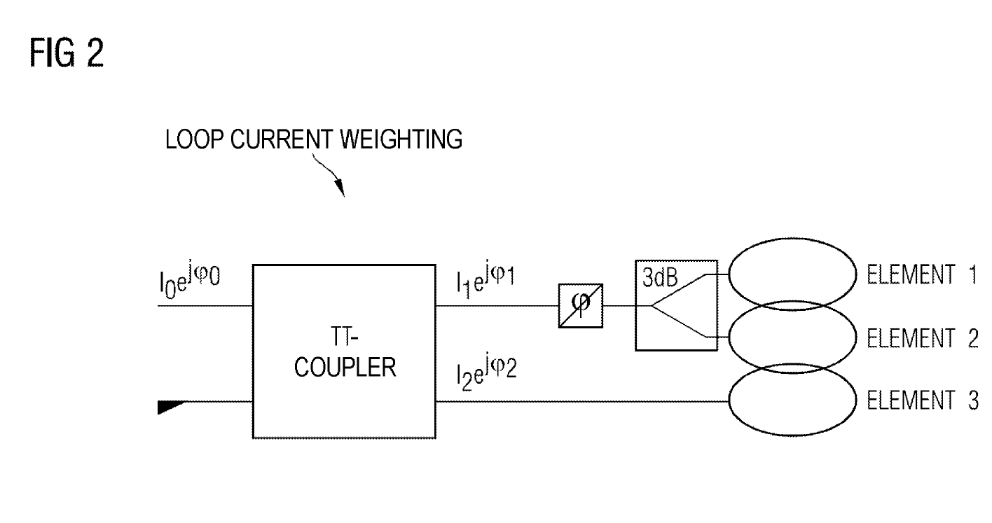

FIG. 2 depicts the circuitry setup of a feed LOOP CURRENT WEIGHTING of the loops, in which the range of ideal circular excitation may additionally be adjusted or optimized by additional weighting of the individual loop currents I_{0 . . . 2} in the three elements.

This optional asymmetrical current distribution may be realized in the case of a hardware setup as depicted, e.g., by an asymmetrical 180° coupler p-COUPLER and additional phase shifters j.

An efficient excitation field is made available using the depicted exemplary embodiments, in which attention was paid to a sufficient element size and decoupling in the design of the antenna structure that includes a plurality of individual elements. The invention is therefore not restricted to the embodiments described, but rather includes all developments, in particular as long as they orient themselves along this inventive concept, in particular along the depicted exemplary embodiments.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A transmission antenna apparatus for emitting transmission magnetic fields in magnetic resonance tomography scanners, the transmission antenna apparatus comprising:
at least a first flat antenna; and
a second flat antenna,
wherein the first flat antenna is arranged in relation to the second flat antenna such that first areas, formed in a planar extent of partial structures of the first flat antenna in each case situated in a same plane, are opposite to second areas, formed in a planar extent of partial structures of the second flat antenna in each case situated in a same plane, in a manner mirrored in a mirror plane, and
wherein the first flat antenna and the second flat antenna, as part of a spatial structure thereof, share a first path, situated on the mirror plane, over a full length of the first path.

2. The transmission antenna apparatus as claimed in claim 1, wherein at least one of the flat antennas is a planar antenna.

3. The transmission antenna apparatus as claimed in claim 1, wherein at least one of the flat antennas is a loop antenna.

4. The transmission antenna apparatus as claimed in claim 1, wherein the partial structures of the flat antennas are configured such that, in respect of the areas thereof emerging in the planar extent, the partial structures are maximized in terms of size such that the partial structures take full advantage of space available in accordance with a design of the magnetic resonance imaging scanners.

5. The transmission antenna apparatus as claimed in claim 1, further comprising:
a third flat antenna, wherein the third flat antenna is formed of coplanar partial structures and arranged in such a way that a plane spanned by partial structures thereof in a planar extent is orthogonal to the mirror plane and shares: (1) a second path, as part of the spatial structure thereof over a full length of the second path with the first flat antenna, and (2) a third path, as part of the spatial structure thereof over a full length of the third path with the second flat antenna.

6. The transmission antenna apparatus as claimed in claim 5, wherein the first flat antenna, the second flat antenna, and the third flat antenna are each a loop antenna.

7. The transmission antenna apparatus as claimed in claim 6, further comprising:
a feed apparatus configured for opposite polarity feed of the first loop antenna and the third loop antenna.

8. The transmission antenna apparatus as claimed in claim 7, wherein the feed apparatus is configured such that the feed apparatus feeds the third loop antenna with an additional phase offset.

9. The transmission antenna apparatus as claimed in claim 8, wherein the feed apparatus is configured such that individual feeds are brought about such that a ratio of values of loop currents of the three loop antennas, generated by the feed, is configured to be set in relation to one another.

10. The transmission antenna apparatus as claimed in claim 9, wherein the feed is configured such that the feed comprises a phase shifter, a 180° phase shifted coupler device, or both the phase shifter and the 180° phase shifted coupler device.

11. The transmission antenna apparatus as claimed in claim 10, wherein common paths are formed by common conductor sections.

12. The transmission antenna apparatus as claimed in claim 7, wherein the feed apparatus is configured such that individual feeds are brought about such that a ratio of values of loop currents of the three loop antennas, generated by the feed, is configured to be set in relation to one another.

13. The transmission antenna apparatus as claimed in claim 5, wherein at least one of the flat antennas is a planar antenna.

14. The transmission antenna apparatus as claimed in claim 5, wherein at least one of the flat antennas is a loop antenna.

15. The transmission antenna apparatus as claimed in claim 5, wherein the partial structures of the flat antennas are configured such that, in respect of the areas thereof emerging in the planar extent, the partial structures are maximized in terms of size such that the partial structures take full advantage of space available in accordance with a design of the magnetic resonance imaging scanners.

16. The transmission antenna apparatus as claimed in claim 1, wherein common paths are formed by common conductor sections.

17. A transmission antenna apparatus comprising:
a first loop antenna;
a second loop antenna; and
a third loop antenna,
wherein the first, the second, and the third loop antennas are applied to a carrier circuit board,
wherein the first loop antenna is arranged parallel to the second loop antenna, and is connected with the second loop antenna by a first central conductor,
wherein the third loop antenna is arranged orthogonally to the first and the second loop antennas, and is connected with (a) the second loop antenna by a second central conductor and (b) the first loop antenna by a third central conductor, therein providing a closed, spatial structure.

18. The transmission antenna apparatus as claimed in claim 17, wherein the transmission antenna apparatus is configured for shoulder imaging of a human torso,
wherein the first loop antenna and the second loop antenna are configured to surround the shoulder from the front and backside of the human torso, and, with the third loop antenna, a field generated for the shoulder imaging may be on three sides of the shoulder reachable from the outside.

19. A magnetic resonance imaging scanner comprising:
a transmission antenna apparatus comprising:
at least a first flat antenna; and
a second flat antenna,
wherein the first flat antenna is arranged in relation to the second flat antenna such that first areas, formed in a planar extent of partial structures of the first flat antenna in each case situated in a same plane, are opposite to second areas, formed in a planar extent of partial structures of the second flat antenna in each case situated in a same plane, in a manner mirrored in a mirror plane, and
wherein the first flat antenna and the second flat antenna, as part of a spatial structure thereof, share a first path, situated on the mirror plane, over a full length of the first path.
